(19) United States
(12) Patent Application Publication
(10) Pub. No.: US 2005/0116235 A1
(43) Pub. Date: Jun. 2, 2005

(54) Illumination assembly

(76) Inventors: John C. Schultz, Afton, MN (US); Donald K. Larson, Cedar Park, TX (US); Michael N. Miller, Austin, TX (US)

Correspondence Address: 3M INNOVATIVE PROPERTIES COMPANY, PO BOX 33427, ST. PAUL, MN, 55133-3427, US

(21) Appl. No.: 10/727,220

(22) Filed: Dec. 2, 2003

(51) Int. Cl. H01L 33/00

(52) U.S. Cl. 257/79

(57) ABSTRACT

An illumination assembly includes a substrate having an electrically insulative layer on a first side of the substrate and an electrically conductive layer on a second side of the substrate. A plurality of LED dies is disposed on the substrate. Each LED die is disposed in a via extending through the electrically insulative layer on the first side of the substrate to the electrically conductive layer on the second side of the substrate. Each LED die is operatively connected through the via to the electrically conductive layer.

### RELATED PATENT APPLICATIONS

The following co-owned and concurrently filed United States patent applications are incorporated herein by reference: “ILLUMINATION SYSTEM USING A PLURALITY OF LIGHT SOURCES”, Ser. No. ______ (Attorney Docket No. 58130US004); “MULTIPLE LED SOURCE AND METHOD FOR ASSEMBLING SAME”, Ser. No. ______ (Attorney Docket No. 59376US002); “SOLID STATE LIGHT DEVICE” Ser. No. ______ (Attorney Docket No. 59349US002); “REFLECTIVE LIGHT COUPLER” Ser. No. ______ (Attorney Docket No. 59121US002); “PHOSPHOR BASED LIGHT SOURCES HAVING A POLYMERIC LONG PASS REFLECTOR” Ser. No. ______ (Attorney Docket No. 58389US004); and “PHOSPHOR BASED LIGHT SOURCES HAVING A NON-PLANAR LONG PASS REFLECTOR” Ser. No. ______(Attorney Docket No. 59416US002).

### BACKGROUND OF THE INVENTION

The present invention generally relates to a lighting or illumination assembly. More particularly, the present invention relates to a package for light emitting elements.

Illumination systems are used in a variety of diverse applications. Traditional illumination systems have used lighting sources such as incandescent or fluorescent lights, for example. More recently, other types of light emitting elements, and LEDs in particular, have been used in illumination systems. LEDs have the advantages of small size, long life and low power consumption. These advantages of LEDs make them useful in many diverse applications.

As the light intensity of LEDs increases, LEDs are more frequently replacing other lighting sources. For many lighting applications, it is generally necessary to have a plurality of LEDs to supply the required light intensity. A plurality of LEDs can be assembled in arrays having small dimensions and a high illuminance or irradiance.

It is possible to achieve an increase in the light intensity of an array of LEDs by increasing the packing density of the individual diodes within the array. An increase in packing density can be achieved by increasing the number of diodes within the array without increasing the space occupied by the array, or by maintaining the number of diodes within the array and decreasing the array dimensions. However, tightly packing large numbers of LEDs in an array is a long-term reliability concern since local heating, even with a globally efficient thermal conduction mechanism, can reduce the lifespan of the LEDs. Therefore, dissipating the heat generated by the array of LEDs becomes more important as the packing density of the LEDs increases.

Conventional LED mounting techniques use packages like that illustrated in United States Patent Application Publication No. 2001/0001207 A1, that are unable to quickly transport the heat generated in the LED junction away from the LED. As a consequence, performance of the device is limited. More recently, thermally enhanced packages have become available, in which LEDs are mounted and wired on electrically insulating but thermally conductive substrates such as ceramics, or with arrays of thermally conductive vias (e.g., United States Patent Application Publication No. 2003/0001488 A1), or using a lead frame to electrically contact a die attached to a thermally conductive and electrically conductive thermal transport medium (e.g., United States Patent Application Publication No. 2002/0113244 A1).

Although the more recent approaches improve the thermal properties of LED arrays, there are several disadvantages to these approaches. Specifically, the substrates, whether they are inorganic material such as ceramic or organic material such as FR4 epoxy, have limited thermal conductivity and the thermal resistance from the heat generating LED to the heat dissipating part of the assembly limits the maximum power dissipation in the LED, and thus the density of the LEDs within the array.

To decrease thermal resistance, it is known to provide thermal vias in organic materials to transfer heat from the LED to the opposite side of the substrate and then to a heat dissipation assembly. However, thermal vias cannot be plated shut due to the potential for trapping plating chemicals in the thermal vias. Therefore, relatively large diameter vias are needed to achieve a low thermal resistance from the LED to the back of the substrate. The size of the thermal vias thus limits the minimum pitch of the LEDs, and the thermal via diameter limits the amount of heat that can be transported by a single via.

In addition, both organic and inorganic substrates have a coefficient of thermal expansion (CTE) associated with the material. As it is preferred to match the CTE of materials within the assembly to reduce the possibility of material delamination during thermal cycling, the choice of other component materials is limited, particularly in the case of a low CTE material such a ceramic that is difficult to match with polymeric materials.

Accordingly, there is a need for a LED package with improved thermal properties.

### SUMMARY OF THE INVENTION

The present invention provides an illumination assembly having improved thermal properties. The assembly includes a substrate having an electrically insulative layer on a first side of the substrate and an electrically conductive layer on a second side of the substrate. A plurality of LEDs are disposed on the substrate. Each LED is disposed in a via extending through the electrically insulative layer on the first side of the substrate to the electrically conductive layer on the second side of the substrate. Each LED is operatively connected through the via to the electrically conductive layer.

In one embodiment, the substrate is flexible, and the electrically conductive layer on the second side of the substrate is thermally conductive. The electrically conductive layer is patterned to define a plurality of electrically isolated heat spreading elements, where each LED is electrically and thermally coupled to an associated heat spreading element. A heat dissipation assembly is disposed adjacent the heat spreading elements, and separated therefrom by a layer of material that is thermally conductive and electrically insulative.

### BRIEF DESCRIPTION OF THE DRAWINGS

FIG. 1 schematically illustrates a perspective view of an embodiment of an illumination assembly according to the invention.

FIG. 2 schematically illustrates a top plan view of the substrate used in the assembly of FIG. 1.

FIG. 3A schematically illustrates a cross-sectional view taken along line 3-3 of FIG. 2.

FIG. 3B schematically illustrates a cross-sectional view of another embodiment of an illumination assembly according to the invention.

FIG. 3C schematically illustrates a cross-sectional view of another embodiment on an illumination assembly according to the invention.

FIG. 4 schematically illustrates a top plan view of a substrate for use with flip-chip-like LEDs.

FIG. 5 schematically illustrates a cross-sectional view taken along line 5-5 of FIG. 4.

FIG. 6 schematically illustrates a top plan view of another substrate embodiment for use with wirebonded LEDs.

FIG. 7 schematically illustrates a cross-sectional view taken along line 7-7 of FIG. 6.

FIG. 8 schematically illustrates a top plan view of another embodiment of a substrate for use with an illumination assembly according to the invention.

FIG. 9 schematically illustrates a cross-sectional view taken along line 9-9 of FIG. 8.

FIGS. 10A-C schematically illustrate an embodiment of an illumination assembly using multilayer optical film.

FIGS. 11A-C schematically illustrate an embodiment of a shaped illumination assembly according to the invention.

### DESCRIPTION OF THE PREFERRED EMBODIMENTS

In the following detailed description of the preferred embodiments, reference is made to the accompanying drawings, which form a part hereof, and in which is shown by way of illustration specific embodiments in which the invention may be practiced. It is to be understood that other embodiments may be utilized and structural or logical changes may be made without departing from the scope of the present invention. The following detailed description, therefore, is not to be taken in a limiting sense, and the scope of the present invention is defined by the appended claims.

As used herein, LED dies include, but are not limited to, light emitting elements such as light emitting diodes (LEDs), laser diodes, and super-radiators, to name a few. LED dies are understood generally as optically emitting semiconductor bodies with contact areas for providing power to the diode.

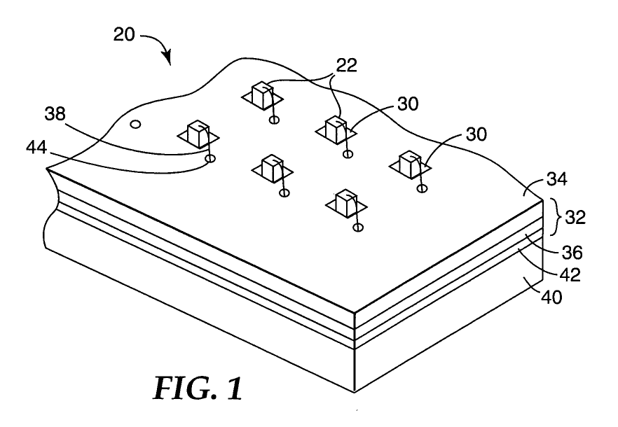

FIG. 1 shows a perspective view of one embodiment of a portion of an illumination assembly 20 according to the invention. The illumination assembly 20 includes a two-dimensional configuration of LED dies 22 disposed in an array. The LED dies 22 can be selected to emit a preferred wavelength, such as in the red, green, blue, ultraviolet, or infrared spectral regions. The LED dies 22 can each emit in the same spectral region, or alternately can emit in different spectral regions.

The LED dies 22 are disposed within vias 30 on a substrate 32. Substrate 32 is comprised of an electrically insulative dielectric layer 34 having a patterned layer 36 of electrically and thermally conductive material disposed on a surface thereof. The vias 30 extend through the dielectric layer 34 to the patterned conductive layer 36, where the LED dies 22 are operatively connected to bond pads (not shown) of the conductive layer 36. The conductive layer 36 of substrate 32 is disposed adjacent a heat sink or heat dissipation assembly 40, and is separated from heat dissipation assembly 40 by a layer 42 of thermally conductive material. The material of layer 42 is also electrically insulative if the heat dissipation assembly 40 is electrically conductive.

Electrically insulative dielectric layer 34 may be comprised of a variety of suitable materials, including polyimide, polyester, polyethyleneterephthalate (PET), multilayer optical film (as disclosed in U.S. Pat. Nos. 5,882,774 and 5,808,794, and incorporated by reference herein in their entirety), polycarbonate, polysulfone, or FR4 epoxy composite, for example.

Electrically and thermally conductive layer 36 may be comprised of a variety of suitable materials, including copper, nickel, gold, aluminum, tin, lead, and combinations thereof, for example.

In one preferred embodiment according to the invention, substrate 32 is flexible and deformable. A suitable flexible substrate 32 having a polyimide insulative layer and copper conductive layer is 3M™ Flexible Circuitry, available from 3M Company of Saint Paul, Minn., U.S.A.

The heat dissipation assembly 40 can be, for example, a heat dissipation device, commonly called a heat sink, made of a thermally conductive metal such as aluminum or copper, or a thermally conductive polymer such as a carbon-filled polymer. The material of layer 42 may be, for example a thermally conductive adhesive material such as a boron nitride loaded polymer, like that available as 3M 2810 from 3M Company, or a thermally conductive non-adhesive material such as a silver filled compound, like that available as Arctic Silver 5 from Arctic Silver Incorporated of Visalia, Calif., U.S.A. In a preferred embodiment, heat dissipation assembly 40 has a thermal resistivity as small as possible, and preferably less than 1.0 C/W. In another embodiment, heat dissipation assembly 40 has a thermal resistivity in the range of 0.5 to 4.0 C/W. The material of layer 42 has a thermal conductivity in the range of 0.2 W/m−K to 10 W/m−K, and preferably at least 1 W/m−K.

In the illumination assembly 20 of FIG. 1, the LED dies 22 illustrated are of the type having one electrical contact on the base of the LED die and another electrical contact on the opposite (top) surface of the LED die. The contact on the base of each LED die 22 is electrically and thermally connected to a bond pad 46a at the bottom of via 30, while the contact on the top of each LED die 22 is electrically connected to the conductive layer 36 by a wirebond 38 extending from LED die 22 to a bond pad 46b at the bottom of via 44. As with vias 30, the vias 44 extend through insulative layer 32 to conductive layer 36. Depending upon the manufacturing process and materials used, vias 30, 44 can be chemically etched, plasma etched, or laser milled through insulative layer 32. During assembly, vias 30 provide the advantage of a convenient alignment point for placing the LED dies 22.

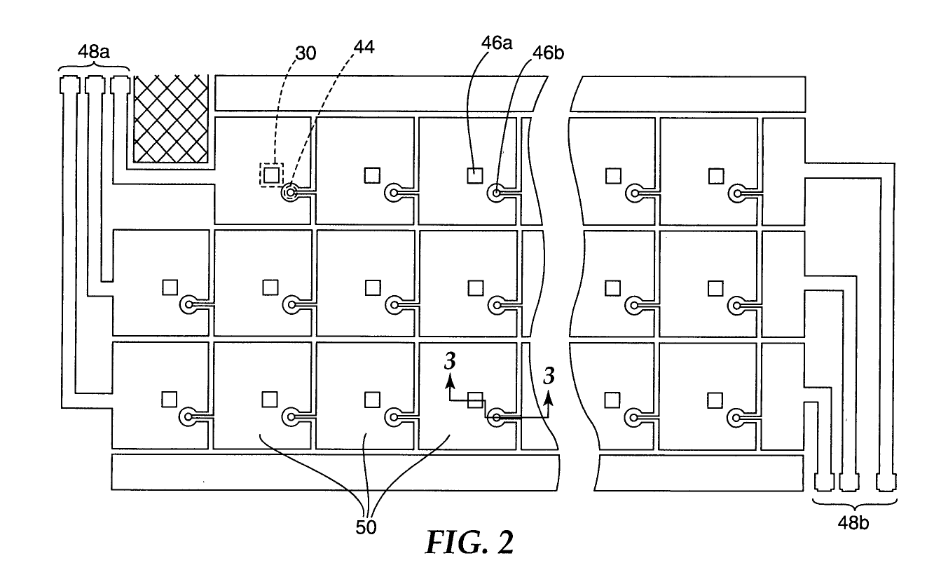

The pattern of conductive layer 36 of FIG. 1 is best seen in FIG. 2. Conductive layer 36 is patterned to define a plurality of electrically isolated heat spreading elements 50. Each heat spreading element 50 is positioned for electrical and thermal coupling to an associated LED die 22 through associated vias 30, 44. For example, for the LED dies illustrated in FIG. 1 having one electrical contact on the diode base and another electrical contact on the top of the diode, the positions of vias 30 and 44 are indicated by dashed lines in FIG. 2. Bonding pads 46a, 46b can be positioned within patterned conductive layer 36 such that LED dies 22 are electrically connected in series between power leads 48a, 48b, based on requirements of the particular application.

As best seen in FIG. 2, instead of patterning conductive layer 36 to provide only narrow conductive wiring traces to electrically connect the LED dies 22, in a preferred embodiment conductive layer 36 is patterned to remove only as much conductive material as is necessary to electrically isolate heat spreading elements 50, leaving as much of conductive layer 36 as possible to act as a heat spreader for the heat generated by LED dies 22. In other embodiments, additional portions of layer 36 can be removed when forming heat spreading elements 50, with a corresponding reduction in the ability of heat spreading elements 50 to conduct heat from the LED dies. Each LED die 22 is therefore in direct contact with a relatively large area of thermally conductive material in layer 36. Each heat spreading element 50 of layer 36 can then efficiently transfer heat from the LED die 22 because of the size of the heat spreading element 50 for each LED die 22. The use of a thermally conductive, electrically insulating material in layer 42 between the conductive layer 36 and the heat dissipating assembly 40 allows an arbitrarily low thermal resistance of the assembly by simply adjusting the pitch of LED dies 22 (and consequently the size of heat spreading elements 50 per LED die 22).

The pitch of heat spreading elements 50 is at least the LED die size (typically on the order of 0.3 mm), but there is no practical upper limit to the pitch, depending upon the requirements of the specific application. In one embodiment, the pitch of heat spreading elements is 2.5 mm.

Although heat spreading elements 50 are illustrated in FIG. 2 as being generally square in shape, heat spreading elements 50 may be rectangular, triangular, or any other shape. Preferably heat spreading elements 50 are shaped to efficiently tile the surface of substrate 32.

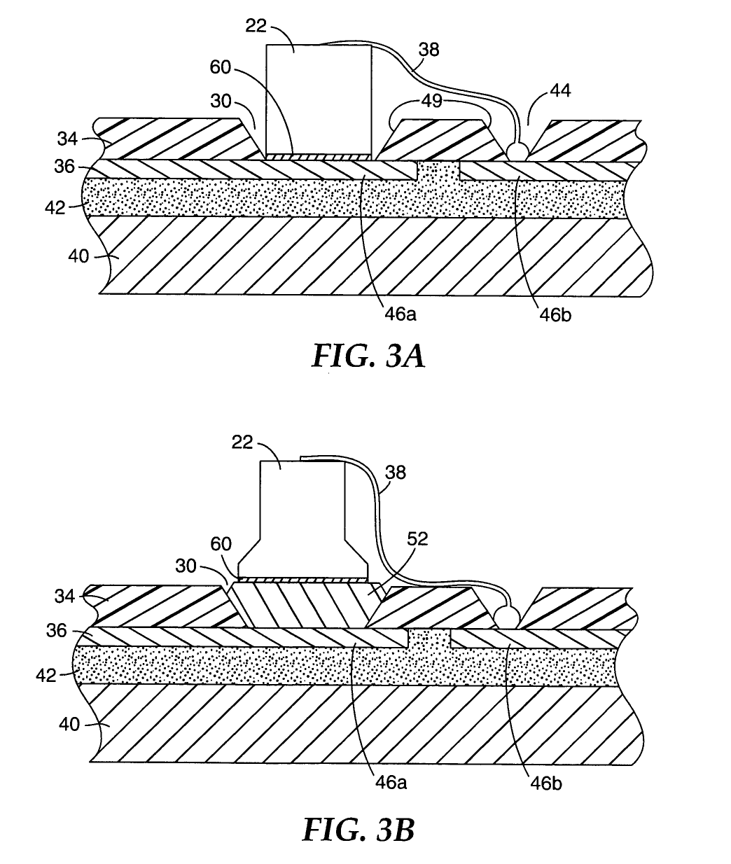

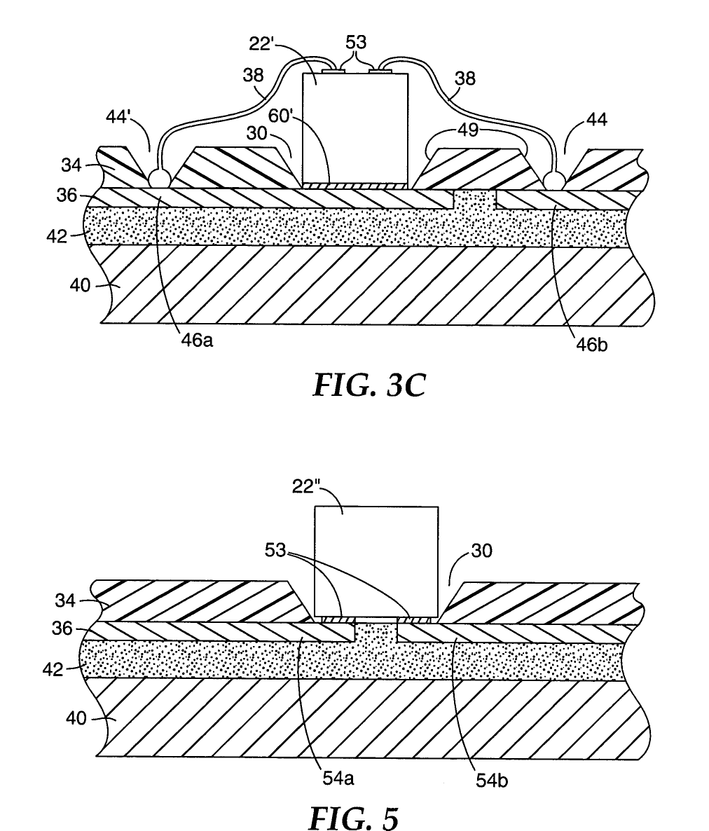

FIG. 3A is an enlarged sectional view taken along line 3-3 of FIG. 2. The LED die 22 is positioned within via 30 and electrically and thermally connected to the bond pad 46a of conductive layer 36 with a layer 60 of either isotropically conductive adhesive (for example, Metech 6144S, available from Metech Incorporated of Elverson, Pa., U.S.A.,), or an anisotropically conductive adhesive, or solder. Solder typically has a lower thermal resistance than an adhesive, but not all LED dies have solderable base metallization. Solder attachment also has the advantage of LED die 22 self-alignment, due to the surface tension of the molten solder during processing. However, some LED dies 22 may be sensitive to solder reflow temperatures, making an adhesive preferable.

In one embodiment, the LED die 22 is nominally 250 micrometers tall, the insulative layer 34 is in the range of 25 to 50 micrometers thick, and the thickness of conductive layer 36 is in the range of 17 to 34 micrometers, but can be varied to more or less than that range based on the power requirements of LED die 22. To facilitate good wirebonding at bond pad 46b, conductive layer 36 can include a surface metallization of nickel and gold. Vias 30 and 44 are illustrated as having sloped side walls 49, as is typical of chemically etched vias. However, vias that are plasma etched or laser milled may have substantially vertical side walls 49.

In some applications, the vertical position of the LED die 22 is critical, as when the LED die 22 is positioned relative to a reflector (not shown). As shown in FIG. 3B, in these instances, metal 52 can be electroplated up in the via 30 to adjust the height of the LED die 22. The electroplated metal 52 can include or be composed of a plated layer of solder, thereby providing a precisely controlled thickness of solder as compared to typical solder paste deposition processes.

FIG. 3C is an enlarged sectional view of a wirebonded LED die 22′ having both electrical contact pads 53 on the same side of the LED die, rather than on opposite sides of the diode as in the wirebonded embodiments of FIGS. 1-3B. Light is emitted from the same side of the diode 22′ that includes contact pads 53. The conductive layer 36 is patterned similar to that in FIG. 2, with bond pad 43a being moved to the bottom of via 44′. The LED die 22′ is positioned within via 30 and thermally connected to conductive layer 36 by a thermally conductive adhesive or solder layer 60′. Layer 60′ is either electrically conductive or electrically insulative depending on the application and LED die 22′ type.

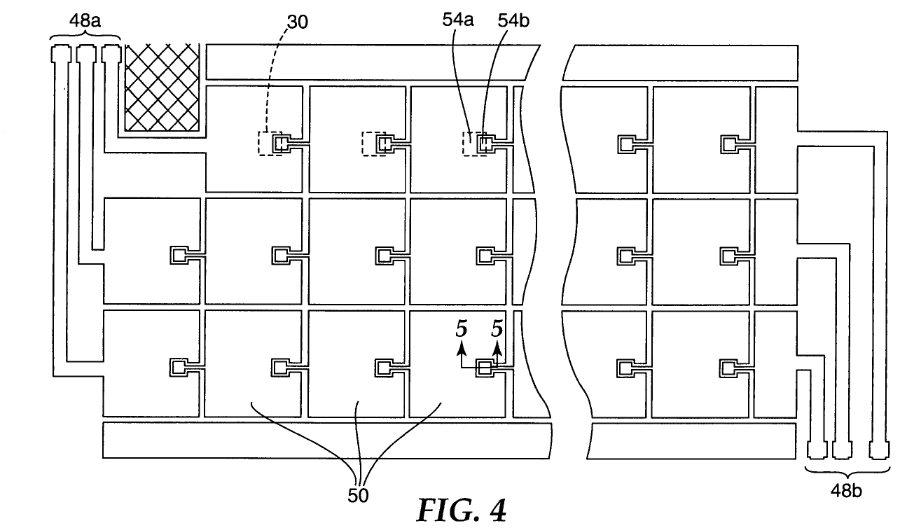

Another embodiment of an illumination assembly according to the invention is illustrated in FIGS. 4 and 5. The embodiment of FIGS. 4 and 5 is intended for use with LED dies 22″ having both electrical contact pads 53 on the same side of the LED die, rather than on opposite sides of the diode as in the wirebonded embodiments of FIGS. 1-3B. Light is emitted from the side of the diode 22″ that is opposite contact pads 53. As best seen in FIG. 4, the conductive layer 36 is patterned to define heat spreading elements 50 and bonding pads 54a, 54b. Because both electrical contact pads 53 are on the same side of the LED die 22″, a single via 30 encompassing electrically separated bonding pads 54a, 54b can be used. The position of via 30 is indicated in dashed lines in FIG. 4, and can be seen to encompass to electrical bond pads 54a, 54b.

FIG. 5 is an enlarged sectional view taken along line 5-5 of FIG. 4. The LED die 22″ is positioned within via 30 and electrically and thermally connected to bond pads 54a, 54b of conductive layer 36. As with the wirebond approach of FIGS. 1-3B, electrically conductive adhesives, anisotropically conductive adhesives, or solder re-flow are among the attachment methods that can be used to attach the LED die 22″ to the conductive substrate 36. As with the wirebond embodiment of FIGS. 1-3B, the flip-chip-like embodiment allows two-dimensional wiring of LED die arrays while providing improved thermal transport through the relatively large heat spreader element 50 attached to the base of the LED die 22″. One advantage of the flip-chip-like embodiment is that the cantilevered bond pads 54a, 54b remain flat, while wirebond solutions may require a significant (100 micrometer) height in order to form the wire bond. In addition, the flip-chip-like configuration adds robustness by eliminating the fragile wirebonds.

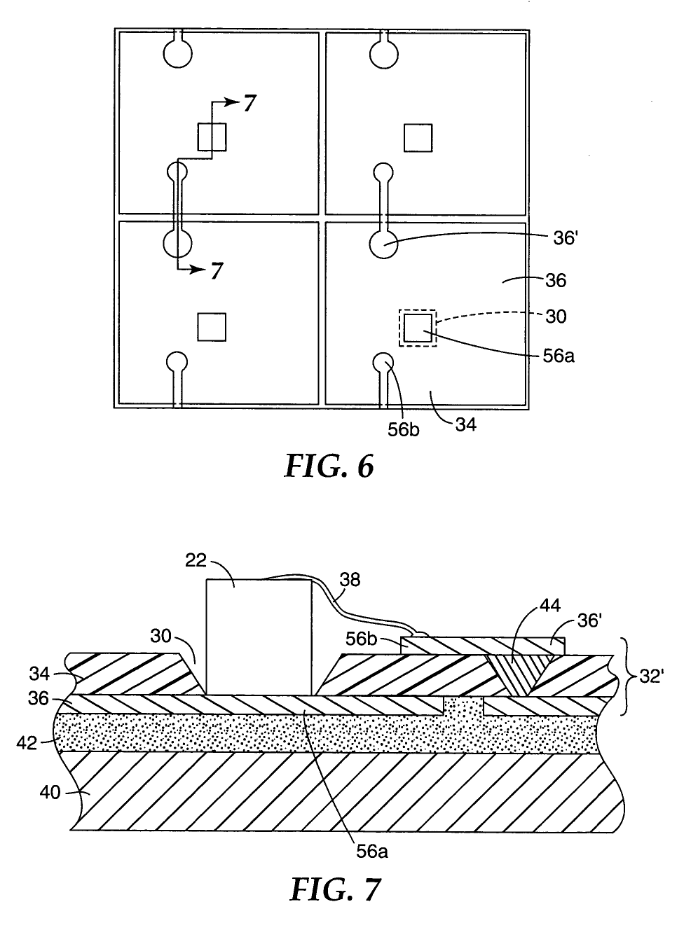

Another embodiment of an illumination assembly according to the invention is illustrated in FIGS. 6 and 7. The embodiment of FIGS. 6 and 7 utilizes what is referred to as a 2-metal substrate 32′, and is intended for use with wirebonded LED dies 22 having electrical contact pads on opposite sides of the diode, as in the embodiments of FIGS. 1-3B. As best seen in FIG. 7, insulative layer 34 includes a second conductive layer 36′ on its top surface. The LED die 22 is positioned within via 30 and electrically and thermally connected to bond pads 56a, 56b of conductive layers 36 and 36′, respectively. Via 44 is filled with conductive material, such as metal, to establish an electrical connection between bond pad 56b of layer 36′ and layer 36. As with the wirebond approach of FIGS. 1-3B, conductive adhesives, anisotropically conductive adhesives, or solder re-flow are among the attachment methods that can be used to attach the LED die 22 to the conductive substrate 36.

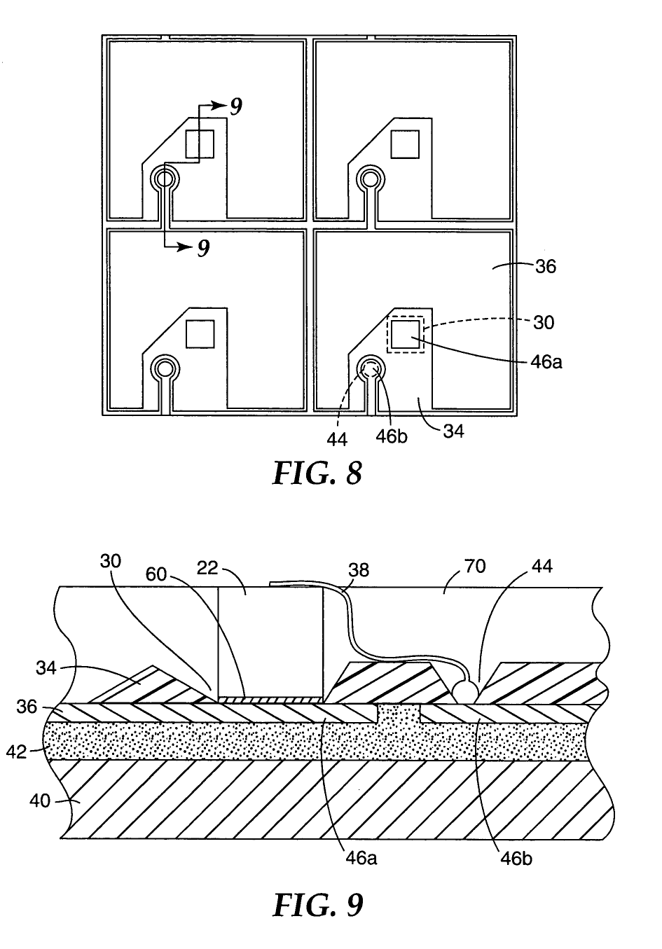

Another embodiment of an illumination assembly 20 is illustrated in FIGS. 8 and 9. In the embodiment of FIGS. 8 and 9, portions of insulative layer 34 are removed to expose conductive layer 36 in areas other than vias 30 and 44. A thermally conductive encapsulant 70 (preferably having a thermal conductivity of greater than 1 W/m−K) is then placed in contact with the LED die and exposed portions of conductive layer 36 to provide an additional heat flow path from the LED die 22 to conductive layer 36. The shape and areas of electrically insulative layer 34 that are removed is determined by manufacturing reliability issues. The embodiment of FIGS. 8 and 9 is also particularly useful with LED dies that emit light from their sides when a transparent, thermally conductive encapsulant is used. A transparent thermally conductive encapsulant is also useful for encapsulating a phosphor layer (for color conversion) on or around the LED die without degrading the LED die light output. Of course, the removal of insulation layer 34 and use of thermally conductive encapsulant 70 is useful for flip-chip-like embodiments like that shown in FIGS. 4 and 5.

In each of the embodiments described herein, a reflective or wavelength-selective material, such as a metalized polymer or a multi-layer optical film (MOF), may be used as an insulative flexible substrate, with patterned electrical traces formed using traditional flexible circuit construction techniques. In one embodiment, layer 36′ of the 2-metal substrate 32′ of FIGS. 6 and 7 is a reflective material such as chrome or silver, and acts as a reflector, as well as (or instead of) a conductive circuit routing layer. Alternately, the reflective layer, with suitable vias, may be laminated to the insulative substrate. Just as LED dies are being used in a number of different applications, the use of light-managing flexible circuitry to package LED dies is also useful in a variety of applications.

Currently, there are a wide variety of LED die arrays available on rigid circuit boards. These arrays can be used for traffic lights, architectural lighting, flood lamps, light fixtures retrofits, and a number of other applications. In currently available configurations, the LED dies are mounted on non-reflective circuit boards. Any light from the LED die that strikes the circuit board is unutilized due to absorption or scattering of the light. By mounting the LED dies on a reflective, flexible circuit, the utilization of the light is improved. Also, due to the flexible nature of the substrate, the arrays can be mounted to conform to the body of the lighting fixture, such as a parabolic shape to focus or direct light.

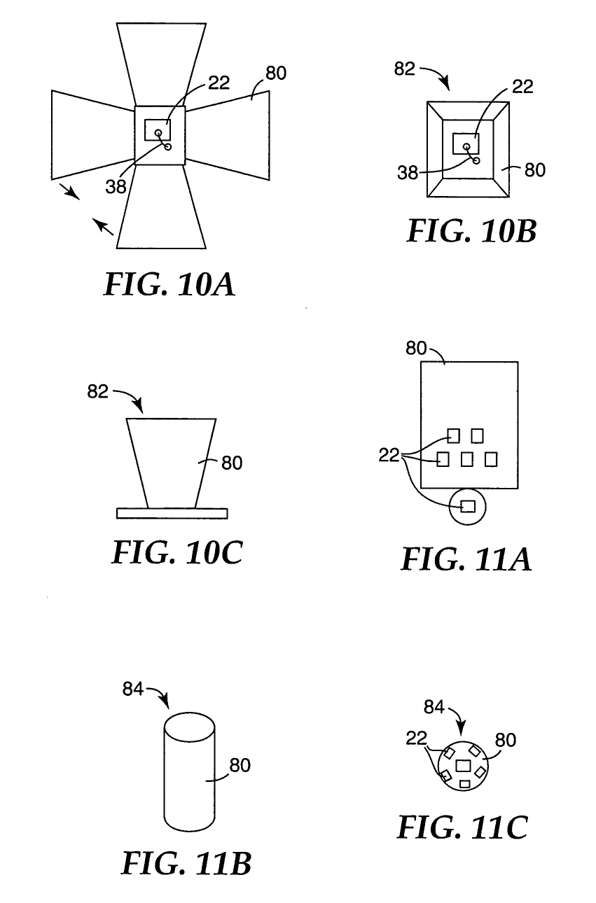

By using reflective surfaced materials, such as multilayer optical film, for the insulative layer 34 in the embodiments described herein, the light reflected from the attached LED dies has a higher probability of being reflected toward the focusing element. As illustrated in FIGS. 10A-C, a LED die 22 can be attached to a planar MOF substrate in any of the manners described herein (FIG. 10A). The multilayer optical film 80 that surrounds the LED die 22 is then folded to create a reflective concentrator 82 around the LED die 22. Side and top views of reflective concentrator 82 are shown in FIGS. 10B and 10C, respectively. As illustrated in FIGS. 11A-C, the planar MOF substrate 80 with attached LED dies 22 (FIG. 11A) can be rolled into a tubular element 84 and used as bright light source. Side and top views of tubular element 84 are shown in FIGS. 11B and 11C, respectively.

The various packages for LED dies described herein offer numerous advantages. The primary advantage is excellent thermal transfer characteristics from the LED die to the conductive layer 36 of substrate 32 and thence to heat dissipation assembly 40.

An additional benefit of the described packages is the low CTE of the substrate material. The CTE of a LED die array placed on the insulative layer 34 and discontinuous conductive heat spreader layer 36, and then adhesively attached to heat dissipation assembly 40 will be dominated by the CTE of the heat dissipation assembly 40, thereby reducing the likelihood of delamination of the various layers during temperature cycling of the device.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiments shown and described without departing from the scope of the present invention. Those with skill in the chemical, mechanical, electromechanical, and electrical arts will readily appreciate that the present invention may be implemented in a very wide variety of embodiments. This application is intended to cover any adaptations or variations of the preferred embodiments discussed herein. Therefore, it is manifestly intended that this invention be limited only by the claims and the equivalents thereof.

1. An illumination assembly comprising:
a substrate comprising an electrically insulative layer on a first side of the substrate and an electrically conductive layer on a second side of the substrate;
a plurality of LED dies, each LED die disposed in a via extending through the electrically insulative layer on the first side of the substrate to the electrically conductive layer on the second side of the substrate, each LED die operatively connected through the via to the electrically conductive layer on the second side of the substrate.

2. The illumination assembly of claim 1, wherein the substrate is flexible.

3. The illumination assembly of claim 1, wherein the electrically insulative layer on the first side of the substrate comprises a material selected from the group comprising polyimide, polyester, polyethyleneterephthalate (PET), optically reflective insulative polymers, multilayer optical film (MOF), polycarbonate, polysulfone, FR4 epoxy composite, and combinations thereof.

4. The illumination assembly of claim 1, wherein the via extending through the electrically insulative material is chemically etched.

5. The illumination assembly of claim 1, wherein the via extending through the electrically insulative material is plasma etched.

6. The illumination assembly of claim 1, wherein the via extending through the electrically insulative material is laser milled.

7. The illumination assembly of claim 1, wherein the electrically conductive layer on the second side of the substrate comprises a material selected from the group comprising copper, nickel, gold, aluminum, tin, lead, or a combination thereof.

8. The illumination assembly of claim 1, wherein the electrically conductive layer on the second side of the substrate comprises a thermally conductive material.

9. The illumination assembly of claim 1, wherein the electrically conductive layer is patterned to define a plurality of electrically isolated heat spreading elements, each LED die electrically and thermally coupled to an associated heat spreading element.

10. The illumination assembly of claim 1, further comprising a heat dissipation assembly disposed adjacent the second side of the substrate.

11. The illumination assembly of claim 10, wherein the heat dissipation assembly is separated from the second side of the substrate by a layer of material that is thermally conductive.

12. The illumination assembly of claim 11, wherein the thermally conductive, material is an adhesive.

13. The illumination assembly of claim 12, wherein the thermally conductive, adhesive material is a polymer adhesive loaded with boron nitride.

14. The illumination assembly of claim 11, wherein the thermally conductive, material is non-adhesive.

15. The illumination assembly of claim 14, wherein the thermally conductive, non-adhesive material is a polymer loaded with silver particles.

16. The illumination assembly of claim 10, wherein the heat dissipation assembly comprises a thermally conductive member.

17. The illumination assembly of claim 16, wherein the thermally conductive member comprises a material selected from the group comprising metals and polymers.

18. An illumination apparatus comprising:
a substrate having an electrically insulative layer on a first surface and an electrically conductive layer on a second surface, a plurality of mounting vias extending through the electrically insulating layer to the electrically conductive layer;
a plurality of light emitting elements disposed in the plurality of mounting vias, wherein the light emitting elements are operatively connected to the electrically conductive layer through the mounting vias.

19. The illumination apparatus of claim 18, wherein the electrically conductive layer is patterned to define a plurality of heat spreading elements

20. The illumination apparatus of claim 18, wherein the light emitting elements are LED dies.

21. The illumination apparatus of claim 18, wherein the light emitting elements are selected from the group comprising light emitting diodes, laser diodes and super-radiators.

22. The illumination apparatus of claim 18, wherein each of the plurality of mounting vias receives a single light emitting element.

23. The illumination apparatus of claim 18, further comprising a plurality of wirebond vias extending through the electrically insulating layer to the electrically conductive layer, each wirebond via exposing a corresponding wirebond connection pad of the electrically conductive layer.

24. The illumination apparatus of claim 18, further comprising a thermally conductive encapsulant contacting the light emitting elements and electrically insulating layer.

25. The illumination apparatus of claim 18, wherein the substrate is flexible.

26. An illumination apparatus comprising:
a layer of electrically insulative material;
a layer of thermally and electrically conductive material disposed on a bottom surface of the layer of insulative material, the conductive material patterned to form a plurality of adjacent heat spreading elements;
a plurality of vias in the insulative material, each via extending through the insulative material to an associated heat spreading element;
a plurality of light emitting elements, each light emitting element disposed in one of the plurality of vias, each light emitting element thermally and electrically coupled to the heat spreading element associated with the via.

27. The illumination apparatus of claim 26, wherein each light emitting element is further electrically coupled to an electrical connection pad of an adjacent heat spreading element.

28. The illumination apparatus of claim 27, wherein each light emitting element is electrically coupled to the electrical connection pad of an adjacent heat spreading element.

29. The illumination apparatus of claim 28, wherein each light emitting element is electrically coupled to the electrical connection pad of an adjacent heat spreading element by a wirebond.

30. The illumination apparatus of claim 27, wherein each light emitting element is electrically coupled to the electrical connection pad of an adjacent heat spreading element within the via.

31. The illumination apparatus of claim 26, wherein the layer of electrically insulative material is flexible.

32. The illumination apparatus of claim 31, wherein the layer of thermally and electrically conductive material is flexible.

33. The illumination apparatus of claim 26, further comprising a heat dissipation assembly thermally coupled to the plurality of heat spreading elements.

34. The illumination apparatus of claim 33, wherein the plurality of heat spreading elements are spatially isolated by a low modulus material such that the illumination apparatus CTE is dominated by the heat dissipation assembly CTE.

35. A flexible circuit comprising:
a flexible layer of electrically insulative material;
a flexible layer of electrically conductive material disposed on a first surface of the insulative material, the conductive material patterned to form a plurality of adjacent heat spreading elements, each heat spreading element having a first electrical connection pad and a second electrical connection pad;
a plurality of mounting vias extending through the insulative material, wherein each mounting via exposes the first electrical connection pad of an associated heat spreading element.

36. The flexible circuit of claim 35, wherein each mounting via further exposes the second electrical connection pad of an adjacent heat spreading element.

37. The flexible circuit of claim 35, further comprising a plurality of connection vias extending through the insulative material, wherein each connection via exposes the second electrical connection pad of an associated heat spreading element.

38. The flexible circuit of claim 35, wherein the insulating material comprises an at least partially reflective multilayer optical film.

39. The flexible circuit of claim 38, wherein the multilayer optical film is shaped into a non-planar light-directing structure.
